(19) United States
(12) Patent Application Publication
(10) Pub. No.: US 2018/0305846 A1
(43) Pub. Date: Oct. 25, 2018

(54) GLASS CLOTH, PREPREG, AND PRINTED WIRING BOARD

(71) Applicant: ASAHI KASEI KABUSHIKI KAISHA, Tokyo (JP)

(72) Inventors: Shinichiro TACHIBANA, Tokyo (JP); Hirotaka KAKIZAKI, Tokyo (JP); Kenichi NAKANISHI, Tokyo (JP); Masaharu SUGIMURA, Tokyo (JP)

(73) Assignee: ASAHI KASEI KABUSHIKI KAISHA, Tokyo (JP)

(21) Appl. No.: 15/892,786

(22) Filed: Feb. 9, 2018

(30) Foreign Application Priority Data
Feb. 10, 2017 (JP) 2017-023527
Feb. 10, 2017 (JP) 2017-023533
Feb. 10, 2017 (JP) 2017-023535
Feb. 10, 2017 (JP) 2017-023560

(51) Int. Cl. D03D 1/00; D03D 15/00; H05K 1/03; H05K 1/02

(52) U.S. Cl. CPC D03D 1/0082; D03D 15/0011; H05K 1/0366; H05K 2201/09136; H05K 1/0271; H05K 2201/029; H05K 1/024

(57) ABSTRACT

The present invention provide a glass cloth comprising a warp yarn and a weft yarn woven together, the warp yarn and the weft yarn each being a glass yarn including multiple glass filaments, wherein at least one of the warp yarn and the weft yarn comprises filaments each having an amount of SiO₂ in the composition thereof of 98 to 100% by mass, an average filament diameter of the glass filaments is 3 to 10 μm, number of the filaments is 20 to 300, each of the weaving densities of the warp yarn and the weft yarn configuring the glass cloth is independently 20 to 140/inch, a thickness of the glass cloth is 5 to 100 μm, an ignition loss of the glass cloth is 0.12% by mass or more but 1.0% by mass or less, a permittivity of the glass cloth is 4.4 or less, and a surface of the glass yarn is treated with a silane coupling agent having an unsaturated double bond group.

### TECHNICAL FIELD

The present invention relates to a glass cloth, a prepreg and a printed wiring board.

### BACKGROUND ART

Currently, as information terminals such as smartphones are increased in high performance and high-speed communication, printed wiring boards to be used therein are remarkably advanced in terms of not only increase in density and large reduction in thickness, but also reduction in permittivity and reduction in dielectric tangent.

As an insulating material for such printed wiring boards, a laminate is widely used which is formed by laminating a prepreg obtained by impregnating a glass cloth with a thermosetting resin (hereinafter, referred to as “matrix resin”.) such as an epoxy resin, and curing the prepreg by heating and compressing. While the permittivity of a matrix resin for use in the above high-speed communication substrate is about 3, the permittivity of a common E glass cloth is about 6.7, and the problem of a high permittivity of a laminate to be formed is increasingly emerged. It is known, as expressed by Edward A. Wolff expression: transmission loss ∞√ε×tan δ, that the lower the permittivity (ε) and the dielectric tangent (tan δ) are, the more suppressed the transmission loss of a signal is.

Therefore, there have been proposed low-permittivity glass cloths of D glass, NE glass, L glass, and the like which are different in composition from E glass (see, for example, Patent Documents 1 to 4).

### CITATION LIST

### Patent Documents

[Patent Document 1] Japanese Unexamined Patent Application Publication No. H5-170483
[Patent Document 2] Japanese Unexamined Patent Application Publication No. 2009-263569
[Patent Document 3] Japanese Unexamined Patent Application Publication No. 2009-19150
[Patent Document 4] Japanese Unexamined Patent Application Publication No. 2009-263824

### SUMMARY OF INVENTION

### Technical Problem

There is, however, still room for improvement in such low-permittivity glass cloths in view of achieving sufficient transmission rate performance in a 5G communication application in the future. Then, it can be conceived to adjust the amount of blending of SiO₂ in a glass composition to almost 100% in attempt to thereby further reduce permittivity and dielectric tangent. If the amount of blending of SiO₂ in glass composition, however, is increased to almost 100%, hole drillability by a mechanical drill commonly used for a low-permittivity substrate may be remarkably deteriorated. Therefore, an interface portion between resin and glass is easily peeled in hole-drilling, and when a copper-plating treatment is made thereafter, a copper-plating liquid easily penetrates into the interface. As a result, the problem of deterioration in insulation reliability between holes of a laminate can be caused.

A first object of the present invention, which is in view of the above problems, is to provide a glass cloth which enables preparation of a substrate having low permittivity and excellent insulation reliability (“substrate” is intended to encompass a prepreg, a printed wiring board, a laminate thereof, and the like), as well as a prepreg and a printed wiring board using the glass cloth.

Next, as a method of improving the hole drillability, a method may be adopted which includes weaving together a common glass yarn and a glass yarn in which the amount of blending of SiO₂ is almost 100%. In particular, a glass yarn in which the amount of blending of SiO₂ is almost 100% can be used as a weft yarn hardly having an adverse effect on mechanical drillability, resulting in an improvement in mechanical drillability. However, because of anisotropy based on the difference in characteristics between a warp yarn and a weft yarn, and deterioration in quality such as bias filling (bowed filling) and fluff due to a thick filament diameter, problems about warpage property of a substrate and also dimensional stability of a substrate may cause. If the dimensional stability is inferior, there is the following tendency: wiring and processing cannot be performed according to a design and a printed wiring board cannot be mass-produced.

A second object of the present invention, which is in view of the above problems, is to provide a glass cloth which enables preparation of a substrate having low permittivity and excellent dimensional stability, and a prepreg and a printed wiring board using the glass cloth.

In addition, if the amount of blending of SiO₂ is almost 100%, bending resistance of a glass filament tends to be considerably deteriorated, and a glass filament may be cracked and/or folded.

The glass filament cracked and/or folded contributes to fluffing of a glass cloth. In the case of a glass filament in which the amount of blending of SiO₂ is increased, a fluffing portion tends to vertically stand, and thus such a fluffing portion is more easily apparent.

Furthermore, if the fluffing portion touches a conductive layer in substrate preparation, interlayer insulation failure may be caused. Thus, there is still room for improvement in view of achieving a substrate excellent in interlayer insulation reliability.

A third object of the present invention, which is in view of the above problems, is to provide a glass cloth which enables preparation of a substrate having low permittivity and excellent interlayer insulation reliability, and a prepreg and a printed wiring board using the glass cloth.

### Solution to Problem

The present inventors have intensively studied to solve the problems (achieve the first object to third object of the present invention), and as a result, have found that the problems can be solved by a predetermined glass cloth, thereby leading to completion of the present invention.

First, the present invention includes first aspect to fourth aspect of the invention.

The first aspect of the invention is as follows.

[1]

A glass cloth comprising glass yarn woven together, the glass yarn comprising multiple glass filaments, wherein

an amount of SiO₂ in a composition of the glass filaments is 98 to 100% by mass,

an average filament diameter of the glass filaments is 3 to 10 μm,

number of the glass filaments is 20 to 300,

each of weaving densities of a warp yarn and a weft yarn configuring the glass cloth is independently 20 to 140/inch,

a thickness of the glass cloth is 8 to 100 μm,

an ignition loss of the glass cloth is 0.12% by mass or more but 0.40% by mass or less,

a permittivity of the glass cloth is 3.8 or less, and

a surface of the glass yarn is treated with a silane coupling agent having an unsaturated double bond group.

[2]

The glass cloth according to [1], wherein the ignition loss of the glass cloth is 0.2% by mass or more but 0.40% by mass or less.

[3]

The glass cloth according to [1] or [2], wherein the surface of the glass yarn is treated with two or more of the silane coupling agents different in molecular weight.

[4]

The glass cloth according to any one of [1] to [3], wherein the amount of SiO₂ in the composition is 98 to 99.95% by mass.

[5]

A prepreg comprising:

the glass cloth according to any one of [1] to [4], and

a matrix resin with which the glass cloth is impregnated.

[6]

A printed wiring board comprising the prepreg according to [5].

The second aspect of the invention is as follows.

[1]

A glass cloth comprising a warp yarn and a weft yarn woven together, the warp yarn and the weft yarn each being a glass yarn comprising multiple glass filaments, wherein

one of the warp yarn and the weft yarn is a glass yarn comprising glass filaments each having an amount of SiO₂ in a composition thereof of 98 to 100% by mass,

the other of the warp yarn and the weft yarn is a glass yarn comprising glass filaments each having an amount of SiO₂ in a composition thereof of 45 to 60% by mass and an amount of B₂O₃ in a composition thereof of 15 to 30% by mass,

each of average filament diameters of the glass filaments configuring the warp yarn and the weft yarn is independently 3 to 10 μm,

each of numbers of the filaments of the warp yarn and the weft yarn is independently 20 to 300, each of weaving densities of the warp yarn and the weft yarn is 20 to 140/inch,

a thickness of the glass cloth is 8 to 100 μm,

an ignition loss of the glass cloth is 0.2% by mass or more but 1.0% by mass or less,

a permittivity of the glass cloth is more than 3.8 but 4.4 or less, and

a surface of the glass yarn is treated with a silane coupling agent having an unsaturated double bond group.

[2]

The glass cloth according to [1], wherein the ignition loss of the glass cloth is 0.3% by mass or more but 0.8% by mass or less.

[3]

The glass cloth according to [1] or [2], wherein the surface of the glass yarn is treated with two or more of the silane coupling agents different in molecular weight.

[4]

The glass cloth according to any one of [1] to [3], wherein one of the warp yarn and the weft yarn is a glass yarn comprising glass filaments each having an amount of SiO₂ in a composition thereof of 98 to 99.95% by mass.

[5]

The glass cloth according to any one of [1] to [4], wherein the other of the warp yarn and the weft yarn is a glass yarn comprising glass filaments each having an amount of SiO₂ in a composition thereof of 50 to 60% by mass and an amount of B₂O₃ in a composition thereof of 20 to 30% by mass.

[6]

A prepreg comprising:

the glass cloth according to any one of [1] to [5], and

a matrix resin with which the glass cloth is impregnated.

[7]

A printed wiring board comprising the prepreg according to [6].

The third aspect of the invention is as follows.

[1]

A glass cloth comprising a warp yarn and a weft yarn woven together, the warp yarn and the weft yarn each being a glass yarn comprising multiple glass filaments, wherein

each of average filament diameters of the glass filaments configuring the warp yarn and the weft yarn is independently 3 to 10 μm,

each of numbers of the filaments of the warp yarn and the weft yarn is independently 20 to 300,

each of weaving densities of the warp yarn and the weft yarn is 20 to 140/inch,

a permittivity of the glass cloth is 4.4 or less, and

a warpage of a printed wiring board formed by the glass cloth is 10 mm or less.

[2]

The glass cloth according to [1], wherein one of the warp yarn and the weft yarn is a glass yarn comprising glass filaments each having an amount of SiO₂ in a composition thereof of 98 to 100% by mass,

the other of the warp yarn and the weft yarn is a glass yarn comprising glass filaments each having an amount of SiO₂ in a composition thereof of 45 to 60% by mass and an amount of B₂O₃ in a composition thereof of 15 to 30% by mass, and

a permittivity of the glass cloth is more than 3.8 but 4.4 or less.

[3]

The glass cloth according to [1] or [2], wherein an average filament diameter of the glass filaments each having an amount of SiO₂ in a composition thereof of 98 to 100% by mass is 6 to 9 μm.

[4]

The glass cloth according to any one of [1] to [3], having a thickness of 30 to 90 μm.

[5]

The glass cloth according to any one of [1] to [4], wherein a tensile modulus of the glass yarn comprising the glass filaments each having an amount of SiO₂ in a composition thereof of 98 to 100% by mass is 70 GPa or more, and

a ratio of the tensile modulus of the glass yarn comprising the glass filaments each having an amount of SiO₂ in a composition thereof of 98 to 100% by mass to a tensile modulus of the glass yarn comprising the glass filaments each having an amount of SiO₂ in a composition thereof of 45 to 60% by mass and an amount of B₂O₃ in a composition thereof of 15 to 30% by mass is 1.3 or less.

[6]

The glass cloth according to any one of [1] to [5], wherein one of the warp yarn and the weft yarn is a glass yarn comprising glass filaments each having an amount of SiO₂ in a composition thereof of 98 to 99.95% by mass.

[7]

The glass cloth according to any one of [1] to [6], wherein the other of the warp yarn and the weft yarn is a glass yarn comprising glass filaments each having an amount of SiO₂ in a composition thereof of 50 to 60% by mass and an amount of B₂O₃ in a composition thereof of 20 to 30% by mass.

[8]

The glass cloth according to any one of [1] to [7], wherein an ignition loss of the glass cloth is 0.2% by mass or more but 1.0% by mass or less.

[9]

The glass cloth according to any one of [1] to [8], wherein a bias filling between the weft yarn and the warp yarn of the glass cloth is 0 to 20 mm per meter as measured with the glass yarns of one of the weft yarn and the warp yarn vertically located.

[10]

The glass cloth according to any one of [1] to [9], wherein a surface of the glass yarn is treated with a silane coupling agent.

[11]

A prepreg comprising:

the glass cloth according to any one of [1] to [10], and

a matrix resin with which the glass cloth is impregnated.

A printed wiring board comprising the prepreg according to [11].

The fourth aspect of the invention is as follows.

[1]

A glass cloth comprising a warp yarn and a weft yarn woven together, the warp yarn and the weft yarn each being a glass yarn comprising multiple glass filaments, wherein

each of average filament diameters of the glass filaments configuring the warp yarn and the weft yarn is 3 μm to 10 μm,

each of numbers of the filaments of the warp yarn and the weft yarn is 20 to 300,

each of weaving densities of the warp yarn and the weft yarn is 20 to 140/inch,

a thickness of the glass cloth is 8 μm to 100 μm, and

number of fluffs having a length of 1 mm or more, observed in application of a tension of 100 N/1000 mm by Roll-to-Roll, is 10/m² or less.

[2]

The glass cloth according to [1], wherein the number of glass filaments of each of the warp yarn and the weft yarn, aligned in a Z direction, is independently 8 or less.

[3]

The glass cloth according to [1] or [2], wherein an ignition loss of the glass cloth is 0.2% by mass or more but 1.0% by mass or less.

[4]

The glass cloth according to any one of [1] to [3], wherein the amount of SiO₂ in a composition of one of the warp yarn and the weft yarn is 98% by mass or more but 100% by mass or less.

[5]

The glass cloth according to any one of [1] to [4], wherein the amount of SiO₂ in a composition of one of the warp yarn and the weft yarn is 98% by mass or more but 99.99% by mass or less.

[6]

The glass cloth according to any one of [1] to [5], wherein a permittivity of the glass cloth is 4.3 or less.

[7]

The glass cloth according to any one of [1] to [6], wherein a surface of the glass yarn is treated with a silane coupling agent.

[8]

A method for producing a glass cloth, comprising:

a sizing step of attaching 2% by mass or more but 10% by mass or less of a sizing agent to a glass yarn,

a weaving step of weaving a glass cloth using the glass yarn obtained in the sizing step as each of a warp yarn and a weft yarn, and

a desizing step of removing the sizing agent attached to the glass cloth obtained in the weaving step, to adjust the amount of the sizing agent attached to 0.1% by mass or less.

[9]

The method for producing the glass cloth according to [8], wherein the sizing step is performed multiple times before the desizing step.

[10]

The method for producing the glass cloth according to [8] or [9], wherein the sizing agent comprises at least one selected from the group consisting of starch, polyvinyl alcohol, polyethylene oxide, polyester and polyamide.

[11]

A prepreg comprising:

the glass cloth according to any one of [1] to [7], and

a matrix resin with which the glass cloth is impregnated.

[12]

A printed wiring board comprising the prepreg according to [11].

While the present invention may be configured from the first to fourth aspects of the invention, the present invention is summarized as follows.

[1]

A glass cloth comprising a warp yarn and a weft yarn woven together, the warp yarn and the weft yarn each being a glass yarn comprising multiple glass filaments, wherein

at least one of the warp yarn and the weft yarn comprises filaments each having an amount of SiO₂ in a composition thereof of 98 to 100% by mass,

an average filament diameter of the glass filaments is 3 to 10 μm,

number of the glass filaments is 20 to 300,

each of weaving densities of the warp yarn and the weft yarn configuring the glass cloth is independently 20 to 140/inch,

a thickness of the glass cloth is 5 to 100 μm,

an ignition loss of the glass cloth is 0.12% by mass or more but 1.0% by mass or less,

a permittivity of the glass cloth is 4.4 or less, and

a surface of the glass yarn is treated with a silane coupling agent having an unsaturated double bond group.

[2]

The glass cloth according to [1], wherein one of the warp yarn and the weft yarn is a glass yarn comprising glass filaments each having an amount of SiO₂ in a composition thereof of 98 to 100% by mass, and the other of the warp yarn and the weft yarn is a glass yarn comprising glass filaments each having an amount of SiO₂ in a composition thereof of 45 to 60% by mass and an amount of B₂O₃ in a composition thereof of 15 to 30% by mass.

[3]

The glass cloth according to [1] or [2], wherein a warpage of a printed wiring board formed by the glass cloth is 10 mm or less.

[4]

The glass cloth according to [2] or [3], wherein a tensile modulus of the glass yarn having an amount of SiO₂ in a composition thereof of 98 to 100% by mass is 70 GPa or more, and a ratio of the tensile modulus of the glass yarn having an amount of SiO₂ in a composition thereof of 98 to 100% by mass to a tensile modulus of the glass yarn having an amount of SiO₂ in a composition thereof of 45 to 60% by mass and an amount of B₂O₃ in a composition thereof of 15 to 30% by mass is 1.3 or less.

[5]

The glass cloth according to any of [1] to [4], wherein a bias filling between the weft yarn and the warp yarn of the glass cloth is 0 to 20 mm per meter as measured with the glass yarns of one of the weft yarn and the warp yarn vertically located.

[6]

The glass cloth according to any of [1] to [5], wherein number of fluffs having a length of 1 mm or more, as observed in application of a tension of 100 N/1000 mm by Roll-to-Roll, is 10/m² or less.

[7]

The glass cloth according to any of [1] to [6], wherein the number of glass filaments of each of the warp yarn and the weft yarn, aligned in a Z direction, is independently 8 or less.

[8]

The glass cloth according to any one of [1] to [7], wherein the surface of the glass yarn is treated with two or more of the silane coupling agents different in molecular weight.

[9]

A prepreg comprising the glass cloth according to any one of [1] to [8], and a matrix resin with which the glass cloth is impregnated.

[10]

A printed wiring board comprising the prepreg according to [9].

### Advantageous Effects of Invention

The first and second aspects of the present invention can provide a glass cloth which can achieve the first object of the present invention and which enables preparation of a substrate having low permittivity and excellent insulation reliability, as well as a prepreg and a printed wiring board using the glass cloth.

The third aspect of the invention can provide a glass cloth which can achieve the second object of the present invention and which enables preparation of a substrate having low permittivity and excellent dimensional stability, and a prepreg and a printed wiring board using the glass cloth.

The fourth aspect of the invention can provide a glass cloth which can achieve the third object of the present invention and which enables preparation of a substrate having low permittivity and excellent interlayer insulation reliability, and a prepreg and a printed wiring board using the glass cloth.

### DESCRIPTION OF EMBODIMENTS

Hereinafter, an embodiment of the present invention (hereinafter, referred to as “the present embodiment”.) will be explained in detail, but the present invention is not limited thereto and can be variously modified within the scope not departing from the gist of the present invention.

### [Glass Cloth]

A glass cloth of the present embodiment is

a glass cloth comprising a warp yarn and a weft yarn woven together, the warp yarn and the weft yarn each being a glass yarn comprising multiple glass filaments, wherein

at least one of the warp yarn and the weft yarn comprises filaments each having an amount of SiO₂ in a composition thereof of 98 to 100% by mass,

an average filament diameter of the glass filaments is 3 to 10 μm,

number of the glass filaments is 20 to 300,

each of the weaving densities of the warp yarn and the weft yarn configuring the glass cloth is independently 20 to 140/inch,

a thickness of the glass cloth is 5 to 100 μm,

an ignition loss of the glass cloth is 0.12% by mass or more but 1.0% by mass or less,

a permittivity of the glass cloth is 4.4 or less, and

a surface of the glass yarn is treated with a silane coupling agent having an unsaturated double bond group.

When the amount of SiO₂ in the composition is 98 to 100% by mass, reduction in permittivity is achieved, but drillability of a substrate tends to be remarkably deteriorated. While the Vickers hardness of common glass is about 640 kgf/mm², the Vickers hardness of glass having an amount of SiO₂ in the composition thereof of almost 100% is about 820 kgf/mm², to cause the tip of a drill chip to be remarkably easily worn in drilling. Therefore, a drillhole whose inner wall is rough and whose shape is irregular is generated, and peeling (peeling portion) easily occurs at a glass/resin interface in such an inner wall. When a copper-plating treatment or the like is performed, a plating liquid easily penetrates into the glass cloth through the peeling portion, and insulation reliability tends to be deteriorated.

In addition, glass filaments are considerably deteriorated in bending resistance and thus may be cracked and/or folded when the amount of SiO₂ in the composition thereof is 98 to 100% by mass. The glass filaments cracked and/or folded contribute to fluffing of a glass cloth. Such fluffing can be caused in a spreading step or the like of the glass cloth, and it is not thus easy to produce easily a glass cloth having no fluffing using glass filaments each having an amount of SiO₂ in the composition thereof of 98 to 100% by mass. In particular, a warp yarn, in the form of a glass yarn, is frequently in contact with a member such as a roll in a warping and weaving step, thereby causing fluffing to more easily occur. In a prepreg application, such glass filaments low in bending resistance cause fluffing in processing and thus tend to be inferior in practicality. Such fluffing causes a fluffing portion to probably touch a conductive layer in preparation of a laminate, resulting in the occurrence of protrusion failure and/or interlayer insulation failure. Accordingly, a glass cloth in which glass filaments having an amount of SiO₂ in the composition thereof of 98 to 100% by mass are used has been conventionally assumed to be problematic in term of practicality.

The glass cloth of the present embodiment, however, can be a glass cloth comprising a warp yarn and a weft yarn woven together, the warp yarn and the weft yarn each being a glass yarn comprising multiple glass filaments, wherein at least one of the warp yarn and the weft yarn has an amount of SiO₂ in the composition thereof of 98 to 100% by mass, the surface of the glass yarn is treated with a silane coupling agent having an unsaturated double bond group, and the ignition loss of the glass cloth is 0.12% by mass or more but 1.0% by mass or less, preferably 0.12% by mass or more but 0.4% by mass or less, and thus there can be provided a glass cloth which can be enhanced in bending resistance of glass filaments with a low permittivity being utilized, and which enables preparation of a substrate having much lower permittivity and more excellent insulation reliability than conventional one. Furthermore, a substrate where the glass cloth of the present embodiment is used much more achieves reduction in permittivity and reduction in dielectric tangent, and can achieve each performance demanded according to increase in high-speed communication.

In particular, one of the warp yarn and the weft yarn is a glass yarn comprising glass filaments each having an amount of SiO₂ in a composition thereof of 98 to 100% by mass, other of the warp yarn and the weft yarn is a glass yarn comprising glass filaments each having an amount of SiO₂ in a composition thereof of 45 to 60% by mass and an amount of B₂O₃ in a composition thereof of 15 to 30% by mass, the surface of the glass yarn is treated with a silane coupling agent having an unsaturated double bond group and the ignition loss of the glass cloth is 0.2% by mass or more but 1.0% by mass or less. Thus, there can be provided a glass cloth which can be enhanced in bending resistance of glass filaments with a low permittivity being utilized and which enables preparation of a substrate having much lower permittivity and more excellent insulation reliability than conventional one. Furthermore, a substrate where the glass cloth of the present embodiment is used much more achieves reduction in permittivity and reduction in dielectric tangent, and can achieve each performance demanded according to increase in high-speed communication.

Next, as the method of improving the hole drillability, a method may be adopted which includes weaving together a common glass yarn and a glass yarn in which the amount of blending of SiO₂ is almost 100%. In this case, anisotropy due to the difference in characteristics between the warp yarn and the weft yarn may be of concern, resulting in a problem about dimensional stability of a substrate.

According to the glass cloth of the present embodiment, however, the warpage of a printed wiring board formed from the glass cloth can be 10 mm or less, thereby providing a glass cloth which enables preparation of a substrate having excellent dimensional stability.

That is, the present inventors have intensively studied, and, as a result, have found that, when the glass cloth of the present embodiment, namely, a glass cloth satisfying a condition where the warpage of a substrate, observed in preparation under a predetermined condition, is a certain value or less is selected and used, a substrate decreased in the dimensional change rate in the warp yarn direction/weft yarn direction can be realized. Although the detail of a mechanism where the glass cloth satisfying the certain condition allows a substrate decreased in the dimensional change rate to be realized is not clear, it is considered that various external forces to be applied to the glass cloth in a yarn-feeding step, an impregnation step, a pressing step, a cooling/curing step and the like in substrate preparation cause the difference in physical performance in the warp yarn direction/weft yarn direction of the glass cloth to be expanded, and on the other hand, it is presumed that the difference in physical performance in a glass cloth small in the amount of warpage occurring in a film thickness direction under a certain condition tends to be balanced out and as a result, the difference in physical performance in the warp yarn direction/weft yarn direction is also inhibited from being expanded and thus the dimensional change rate of a substrate to be obtained is decreased.

In addition, any glass filament cracked and/or folded causes fluffing of the glass cloth. Such fluffing can be caused in a water-cleaning and a spreading step after a surface treatment of the glass cloth. In a prepreg application, fluffing may also occur in processing (a case is also encompassed where a small fluff originally generated is changed to a large fluff). In the state where a fluffing portion touches a conductive layer, interlayer insulation failure may occur.

The present inventors have intensively studied and have found that, when the glass cloth of the present embodiment, namely, a glass cloth satisfying a certain condition where the number of fluffs having a certain size or more, observed in application of a certain tension (not observed in application of no tension), is a certain value or less is selected and used, such fluff(s) can be inhibited from touching a conductive layer in substrate preparation and, in turn, a substrate excellent in interlayer insulation reliability can be realized. Although the detail of a mechanism where the glass cloth satisfying the certain condition allows a substrate excellent in interlayer insulation reliability to be realized is not clear, it is considered that various external forces to be applied to the glass cloth in a yarn-feeding step, an impregnation step, a pressing step, a cooling/curing step and the like in substrate preparation cause increase in the number of fluffs, and on the other hand, it is presumed that a glass cloth small in the angle of fluffing and low in the degree of fluffing is suppressed in such increase under a certain tension or is decreased in the angle of fluffing in the course of shrinkage in a cooling/curing step and as a result, the amount of glass in contact with a conductive layer in a substrate to be obtained is decreased.

Herein, the number of fluffs of 1 mm or more can be evaluated according to a method described in Examples.

The number of fluffs is preferably 9/m² or less, more preferably 8/m² or less. Furthermore, the lower limit value of the number of fluffs is ideally 0/m², and may be 1/m² or more or may be 2/m² or more.

The number of fluffs having a length of 1 mm or more can be adjusted to 10/m² or less, for example, by using, as the warp yarn and the weft yarn configuring the glass cloth, a warp yarn and a weft yarn each obtained by a treatment for attachment of a predetermined amount of a sizing agent.

### [Composition of Glass Filament]

In the present embodiment, at least one of the warp yarn and the weft yarn can be a glass yarn comprising glass filaments each having an amount of SiO₂ in the composition thereof of 98 to 100% by mass (hereinafter, referred to as “glass filaments A”.) and the other of the warp yarn and the weft yarn is a glass yarn comprising glass filaments each having an amount of SiO₂ in the composition thereof of 45 to 60% by mass and an amount of B₂O₃ in the composition thereof of 15 to 30% by mass (hereinafter, referred to as “glass filaments B”.). The present mode includes, in addition of a mode where one of the warp yarn and the weft yarn is a glass yarn comprising glass filaments A and the other of the warp yarn and the weft yarn is a glass yarn comprising glass filaments B, a mode where one of the warp yarn and the weft yarn is a glass yarn comprising glass filaments A and glass filaments B and the other of the warp yarn and the weft yarn is a glass yarn comprising glass filaments A or a glass yarn comprising glass filaments B, and a mode where both of the warp yarn and the weft yarn are each a glass yarn comprising glass filaments A and glass filaments B.

In the present embodiment, both of the warp yarn and the weft yarn may be each a glass yarn comprising glass filaments A.

### [Glass Filaments A]

The amount of SiO₂ in the composition of glass filaments A is 98 to 100% by mass, preferably 98 to 99.95% by mass, more preferably 98 to 99% by mass. When the amount of SiO₂ in the composition is 98% by mass or more, permittivity and dielectric tangent tend to be more decreased. In addition, when the amount of SiO₂ in the composition is 98% by mass or more, air incorporation can be suppressed in glass melt-spinning and the occurrence of a hollow yarn can be suppressed. Such a hollow yarn is decreased, thereby resulting in a tendency to more enhance insulation reliability of a substrate. In addition, when the amount of SiO₂ in the composition is 99.95% by mass or less, bending resistance and brittleness resistance of the glass yarn tend to be more enhanced. This results in tendencies to more enhance drillability of a substrate, to hardly cause cutting of the glass yarn in spreading and in water-cleaning after treating and processing of the glass cloth, and to decrease the amount of fluff(s) in the glass cloth. Such a glass cloth can be used to thereby not only result in more reduction in permittivity, but also enhancement in insulation reliability due to decrease of a hollow yarn, enhancement in insulation reliability due to enhancement in drillability of a substrate, and enhancement in insulation reliability due to decrease in fluffing (preventing of plating penetration, protrusion failure, interlayer insulation failure, and the like). The amount of SiO₂ in the composition can be adjusted depending on the amount of a raw material to be used in glass filament preparation.

Glass filaments A may have any composition other than SiO₂. Such other composition is not particularly limited, and examples thereof include Al₂O₃, CaO, MgO, B₂O₃, TiO₂, Na₂O, K₂O, Sr₂O₃ and Fe₂O₃.

### [Glass Filaments B]

The amount of SiO₂ in the composition of glass filaments B is 45 to 60% by mass, preferably 50 to 60% by mass, more preferably 51 to 56% by mass. The amount of B₂O₃ in the composition of glass filaments B is 15 to 30% by mass, preferably 20 to 30% by mass, more preferably 21 to 25% by mass. When the amount of SiO₂ and B₂O₃ in the composition are 60% or less and 15% by mass or more respectively, the glass melt viscosity tends to be decreased to allow the glass yarn to be easily pulled, and thus the occurrence of a hollow yarn can be suppressed and also reduction in permittivity is achieved. When the amount of SiO₂ and B₂O₃ in the composition are 45% or more and 30% by mass or less respectively, moisture absorption resistance is more enhanced in conducting of a surface treatment. On the other hand, if the amount of B₂O₃ in the composition is less than 15% by mass, the number of the hollow yarns is increased and insulation reliability is thus deteriorated. If the amount of B₂O₃ in the composition is decreased to the amount in the composition of E glass, the number of the hollow yarns tends to be decreased, but permittivity is increased. If the amount of B₂O₃ in the composition is more than 30% by mass, the amount of fluff(s) is increased and also the amount of moisture absorption is increased, thereby resulting in deterioration in insulation reliability. The amount of B₂O₃ in the composition can be adjusted depending on the amount of a raw material to be used in glass filament preparation.

Glass filaments B may have any composition other than SiO₂ and B₂O₃. Such other composition is not particularly limited, and examples thereof include Al₂O₃, CaO, MgO, TiO₂, Na₂O, K₂O, Sr₂O₃ and Fe₂O₃.

The amount of composition of Al₂O₃ in glass filaments B is preferably 11 to 16% by mass, more preferably 12 to 16% by mass. When the amount of composition of Al₂O₃ is within the above range, yarn productivity tends to be more enhanced.

The amount of composition of CaO in glass filaments B is preferably 4 to 8% by mass, more preferably 6 to 8% by mass. When the amount of composition of CaO is within the above range, yarn productivity tends to be more enhanced.

### [Average Filament Diameter of Glass Filaments]

Each of the average filament diameters of the glass filaments configuring the warp yarn and the weft yarn can be independently 3 to 10 μm, and is preferably 3.5 to 9.5 μm, more preferably 3.5 to 9.0 μm. When each of the average filament diameters of the glass filaments is within the above range, processability in processing of a substrate to be obtained, by a mechanical drill, tends to be more enhanced. In particular, each of the average filament diameters of the glass filaments is preferably set to 9.5 μm or less because the contact area per unit volume of a matrix resin with the glass filaments is increased, thereby resulting in a tendency to more considerably exert an effect described below by adjusting of the ignition loss to a certain value or more. Herein, when the warp yarn or the weft yarn is a glass yarn comprising glass filaments A or B, each of the average filament diameters corresponds to the average filament diameter of glass filaments A or B configuring the glass yarn, and when the warp yarn or the weft yarn is a glass yarn comprising glass filaments A and B, each of the average filament diameters corresponds to the average filament diameter of glass filaments A and B configuring the glass yarn.

In particular, the average filament diameter of glass filaments A is 3 μm or more, preferably 4 to 10 μm, more preferably 6 to 10 μm, further preferably 7.5 to 10 μm. When the average filament diameter of glass filaments A is 3 μm or more, cutting of glass filaments A tends to be more suppressed to decrease the amount of fluff(s) in the glass cloth, resulting in more enhancement in insulation reliability due to decrease in fluffing. In addition, when the average filament diameter of glass filaments A is 10 μm or less, the contact area per unit volume of a matrix resin with the glass filaments is increased, resulting in a tendency to more considerably exert an effect described below by adjusting of the ignition loss to a certain value or more.

In addition, the average filament diameter of glass filaments B is preferably 3 to 9 μm, more preferably 4 to 8 μm, further preferably 5 to 7 μm. When the average filament diameter of glass filaments B is 3 μm or more, processability of a substrate to be obtained tends to be more enhanced. When the average filament diameter of glass filaments B is 9 μm or less, the contact area per unit volume of a matrix resin with the glass filaments is increased, resulting in a tendency to more considerably exert an effect described below by adjusting of the ignition loss to a certain value or more.

### [Number of Glass Filaments]

The number of the glass filaments configuring each of the warp yarn and the weft yarn can be independently 20 to 300, and is preferably 20 to 200. When the number of the glass filaments is within the above range, processability in processing of a substrate to be obtained, by a mechanical drill, tends to be more enhanced. Herein, when the warp yarn or the weft yarn is a glass yarn comprising glass filaments A or B, the number of the filaments corresponds to the number of glass filaments A or B configuring the glass yarn, and when the warp yarn or the weft yarn is a glass yarn comprising glass filaments A and B, the number of the filaments corresponds to the total number of glass filaments A and B configuring the glass yarn.

In addition, when the warp yarn or the weft yarn is a glass yarn comprising glass filaments A, the number of glass filaments A is preferably 20 to 250, more preferably 50 to 200, further preferably 75 to 150. When the number of glass filaments A is 20 or more, cutting of glass filaments A tends to be more suppressed to decrease the amount of fluff(s) in the glass cloth, resulting in more enhancement in insulation reliability due to decrease in fluffing. In addition, when the number of glass filaments A is 250 or less, a finer glass yarn tends to be able to be achieved with fluff(s) being suppressed, in consideration of the filament diameter.

In addition, when the warp yarn or the weft yarn is a glass yarn comprising glass filaments B, the number of glass filaments B is preferably 50 to 300, more preferably 100 to 275, further preferably 150 to 250. When the number of glass filaments B is 50 or more, processability of a substrate to be obtained tends to be more enhanced. When the number of glass filaments B is 300 or less, a finer glass yarn tends to be able to be achieved in consideration of the filament diameter.

### [Number of Filaments in Z Direction]

Each of the numbers of the filaments in Z direction of the warp yarn and the weft yarn of the glass cloth is preferably 8 or less, more preferably 7 or less, further preferably 6 or less. When each of these numbers of the filaments is 8 or less, drillability can be considerably improved. In particular, when the glass yarn comprising glass filaments A is used, an improvement effect due to using 8 or less filaments is large. When the number is set to 8 or less, there is not any location where the glass cloth is locally thick in the plane thereof, and an improvement effect of interlayer insulation property can be more increased. The number of the filaments in the Z direction can be determined from the maximum value obtained by observation of any twenty yarn bundles with an electron microscope.

### [Weaving Density]

Each of the weaving densities of the warp yarn and the weft yarn configuring the glass cloth is independently 20 to 140/inch, preferably 30 to 130/inch, more preferably 40 to 120/inch.

### [Tensile Modulus]

The tensile modulus of the glass yarn comprising glass filaments A is preferably 70 GPa or more, more preferably 72 GPa or more, further preferably 75 GPa or more. In addition, the tensile modulus of the glass yarn comprising glass filaments A is preferably 100 GPa or less, more preferably 90 GPa or less, further preferably 80 GPa or less. When the tensile modulus of the glass yarn comprising glass filaments A is 70 GPa or more, waviness in the weft or warp yarn direction of the glass cloth tends to be able to be suppressed.

The tensile modulus of the glass yarn comprising glass filaments B is preferably 50 GPa or more, more preferably 55 GPa or more, further preferably 60 GPa or more. In addition, the tensile modulus of the glass yarn comprising glass filaments B is preferably 80 GPa or less, more preferably 75 GPa or less, further preferably 70 GPa or less. When the tensile modulus of the glass yarn comprising glass filaments B is within the above range, cutting (fluff) of the glass filaments tends to be hardly caused. Such a fluff serves as a protrusion in formation of a substrate and is brought into contact with a conductor of copper foil or the like, thereby resulting in a tendency to significantly deteriorate insulation reliability in the Z direction of the substrate. Therefore, when the tensile modulus is within the above range, insulation reliability in the Z direction of a substrate to be obtained tends to be more enhanced.

The ratio of the tensile modulus of the glass yarn comprising glass filaments A to the tensile modulus of the glass yarn comprising glass filaments B is preferably 1.3 or less, more preferably 1.2 or less. When the ratio of the tensile modulus of the glass yarn comprising glass filaments A to the tensile modulus of the glass yarn comprising glass filaments B is 1.3 or less, the difference in anisotropy between the warp and weft yarn directions is smaller to result in a tendency to more suppress warpage of a substrate.

Herein, the tensile moduli can be measured by a method described in Examples.

### [Thickness]

The thickness of the glass cloth is 5 to 100 μm, preferably 8 to 100 μm, more preferably 15 to 90 μm, further preferably 20 to 80 μm.

### [Cloth Weight (Basis Weight)]

The cloth weight (basis weight) of the glass cloth is preferably 6 to 100 g/m², more preferably 7 to 90 g/m².

### [Weave Structure]

The weave structure of the glass cloth is not particularly limited, and examples thereof include weave structures such as plain weave, basket weave, satin weave and twill weave structures. Among them, a plain weave structure is more preferable.

The bias filling between the weft yarn and the warp yarn of the glass cloth is preferably 0 to 20 mm, more preferably 0 to 15 mm, further preferably 0 to 10 mm, per meter, as measured with the glass yarns of one of the weft yarn and the warp yarn vertically located. In the glass cloth of the present embodiment, there is a difference in physical performance between the warp yarn direction and the weft yarn direction, and therefore warpage of a substrate is sometimes easily caused and/or the dimensional change rate is sometimes increased.

In the present embodiment, production is made so that the bias filling between the weft yarn and the warp yarn of the glass cloth is 20 mm or less per meter when measured the glass yarns of one of the weft yarn and the warp yarn vertically located, thereby resulting in decreases in the amount of warpage and the dimensional change rate of a substrate. In order that the bias filling is 20 mm or less, it is effective that the standard deviation of migration attainment in weaving is 5 or less, that the tension in a weaving machine and a processing machine is 100 N/m or more, and that the degree of parallelization between all rolls and all core tubes in the production process is 0.1 mm or less per meter. In the present embodiment, the “bias filling” refers to “the state of a woven fabric where a weft yarn and a warp yarn are not perpendicular to each other” according to JIS R 3410.

The detail of a mechanism where a glass cloth in which the bias filling is a certain value or less enables providing a substrate decreased in the dimensional change rate is not clear. However, it is considered that various external forces to be applied to the glass cloth in a yarn-feeding step, an impregnation step, a pressing step, a cooling/curing step and the like in substrate preparation cause the difference in physical performance in the warp yarn direction/weft yarn direction of the glass cloth to be expanded. On the other hand, it is presumed that the difference in physical performance in a glass cloth small in the amount of bowed filling, under application of an external force, is inhibited from being expanded and that as a result, the dimensional change rate of a substrate to be obtained is decreased.

### [Surface Treatment]

Each of the glass yarns (including glass filaments) of the glass cloth is subjected to a surface treatment with a silane coupling agent having an unsaturated double bond group (hereinafter, simply referred to as “silane coupling agent”.). The silane coupling agent having an unsaturated double bond group is used to thereby more enhance reactivity with a matrix resin, and hardly generate a hydrophilic functional group after a reaction with a matrix resin, to more enhance insulation reliability.

The silane coupling agent having an unsaturated double bond group is not particularly limited, and examples thereof include a compound represented by the following general formula (1). The silane coupling agent having an unsaturated double bond group can be used to thereby improve plating liquid penetration property, insulation reliability, and suppression of fluffing after drilling of a glass cloth having an amount of SiO₂ in the composition of 98 to 100% by mass.

X(R)₃₋ₙSiYₙ (1)

wherein X represents an organic functional group having at least one unsaturated double bond group, each Y independently represents an alkoxy group, n represents an integer of 1 or more but 3 or less, and each R independently represents a group selected from the group consisting of a methyl group, an ethyl group and a phenyl group.

The organic functional group having at least one unsaturated double bond group, represented by X, is not particularly limited, and examples thereof include a vinyl group, an allyl group, a vinylidene group, an acryloxy group and a methacryloxy group.

Any alkoxy group can be used as the above alkoxy group, and the above alkoxy group is preferably an alkoxy group having 5 or less carbon atoms in terms of a stable treatment of the glass cloth.

The silane coupling agent that can be specifically used is not particularly limited, and examples thereof include known substances such as N-β-(N-vinylbenzylaminoethyl)-γ-aminopropyltrimethoxysilane and hydrochloride thereof, N-β-(N-vinylbenzylaminoethyl)-γ-aminopropylmethyldimethoxysilane and hydrochloride thereof, N-β-(N-di(vinylbenzyl)aminoethyl)-γ-aminopropyltrimethoxysilane and hydrochloride thereof, N-β-(N-di(vinylbenzyl)aminoethyl)-N-γ-(N-vinylbenzyl)-γ-aminopropyltrimethoxysilane and hydrochloride thereof, vinyltrimethoxysilane, methacryloxypropyltrimethoxysilane, methacryloxyoctyltrimethoxysilane, and acryloxypropyltrimethoxysilane. The silane coupling agents above tend to be excellent in reactivity with each of the glass yarns (glass filaments) of the glass cloth, and the matrix resin of a substrate, in particular, a radical polymerization-based resin. Therefore, deterioration in insulation reliability due to easy peeling at the interface between the resin and the glass cloth tends to be able to be suppressed, and deterioration in insulation reliability due to penetration of a plating liquid into the glass cloth tends to be able to be suppressed.

The molecular weight of the silane coupling agent is preferably 100 to 600, more preferably 150 to 500, further preferably 200 to 450. In particular, two or more of the above silane coupling agents having an unsaturated double bond group, different in molecular weight, are preferably used. When two or more of the above silane coupling agents different in molecular weight are used to treat the glass yarn surface, the density of the treatment agent on the glass surface tends to be increased and reactivity with the matrix resin tends to be further enhanced. Herein, the amount of the glass cloth to be treated with a surface treatment agent can be estimated based on the following ignition loss.

### [Ignition Loss]

The ignition loss of the glass cloth is 0.12% by mass or more, preferably 0.15% by mass or more, more preferably 0.2% by mass or more, further preferably 0.3% by mass or more. The upper limit of the ignition loss of the glass cloth is 1.0% by mass or less, preferably 0.9% by mass or less, more preferably 0.8% by mass or less, further preferably 0.40% by mass or less, still more preferably 0.35% by mass or less. When the ignition loss of the glass cloth is 0.12% by mass or more, plating liquid penetration property, insulation reliability, and suppression of fluffing, after drilling of the glass cloth comprising filaments having an amount of SiO₂ in the composition thereof of 98 to 100% by mass, can be improved. Furthermore, moisture absorption resistance can be more enhanced, and deterioration in insulation reliability due to moisture absorption can be suppressed. When the ignition loss of the glass cloth is 1.0% by mass or less, resin permeability to the glass cloth is more enhanced, and as a result, insulation reliability is more enhanced.

The “ignition loss” herein can be measured according to the method described in JIS R 3420. That is, the glass cloth is first placed in a drier at 110° C., and dried for 60 minutes. After the drying, the glass cloth is transferred to a desiccator, left to stand for 20 minutes, and cooled to room temperature. After the cooling, the glass cloth is weighed in the unit of 0.1 mg or less. Next, the glass cloth is heated by a muffle furnace at 625° C. for 20 minutes. After the heating by the muffle furnace, the glass cloth is transferred to a desiccator, left to stand for 20 minutes, and cooled to room temperature. After the cooling, the weight of the glass cloth is measured in the unit of 0.1 mg or less. The ignition loss determined by the above measurement method is used to define the amount of the silane coupling agent treated in the glass cloth.

### [Permittivity of Glass Cloth]

The permittivity of the glass cloth is 4.4 or less, preferably 4.2 or less, more preferably 3.8 or less, further preferably 3.7 or less. The permittivity of the glass cloth can be measured by a method described in Examples.

The lower limit value of the permittivity of the glass cloth is ideally 0 and may be more than 0.

### [Method for Producing Glass Cloth]

A method for producing a glass cloth of the present embodiment is not particularly limited, and preferably comprises a sizing step of attaching 2% by mass or more but 10% by mass or less of a sizing agent to a glass yarn, a weaving step of using the glass yarn obtained in the sizing step as each of a warp yarn and a weft yarn to weave a glass cloth, and a desizing step of removing the sizing agent attached to the glass cloth obtained in the weaving step, to adjust the amount of the sizing agent attached to 0.1% by mass or less. The sizing step may be performed multiple times before the desizing step.

When the sizing step is included in the production of the glass cloth, the number of fluffs having a length of 1 mm or more, observed in application of a tension of 100 N/1000 mm by Roll-to-Roll, can be controlled to 10/m² or less.

The sizing step can provide a glass yarn in which the amount of the sizing agent attached is 2% by mass or more but 10% by mass or less. In the sizing step, for example, an aqueous sizing agent solution can be applied to a glass yarn to thereby attach the sizing agent to the glass yarn. The method of applying an aqueous sizing agent solution to a glass yarn can be, for example, a method comprising storing an aqueous sizing agent solution in a bath, and dipping and allowing passage of the glass cloth (hereinafter, referred to as “dip method”.).

In order to adjust the amount of the sizing agent attached, for example, after application of an aqueous sizing agent solution to a glass yarn, a step of squeezing the glass yarn, to which the sizing agent is applied, by a squeeze roll or the like may be included.

The concentration of the sizing agent in the aqueous sizing agent solution is not particularly restricted as long as a glass yarn having an amount of the sizing agent attached of 2% by mass or more but 10% by mass or less can be made, and the concentration is preferably 2% by mass or more but 8% by mass or less, more preferably 2% by mass or more but 5% by mass or less, further preferably 2% by mass or more but 4% by mass or less.

In the desizing step, for example, the glass cloth obtained in the weaving step can be heated to remove the sizing agent attached to the glass yarn, thereby adjusting the amount of the sizing agent attached to 0.1% by mass or less. The heating temperature in the desizing step may be appropriately adjusted depending on the type of the sizing agent used, and the like, and is preferably around 400° C.

The lower limit value of the amount of the sizing agent attached in the sizing step is preferably 2% by mass or more from the viewpoint of stability in weaving and reduction in the number of fluffs. The upper limit value of the amount of the sizing agent attached in the sizing step is preferably 10% by mass or less, more preferably 8% by mass or less, further preferably 5% by mass or less, particularly preferably 4% by mass or less, from the viewpoint that resin permeability to the glass cloth is enhanced to result in enhancement in insulation reliability.

The amount of the sizing agent attached can be determined from the following ignition loss. The “ignition loss” of the glass yarn herein mentioned can be measured according to the method described in JIS R 3420. That is, the glass yarn is first placed in a drier at 110° C., and dried for 60 minutes. After the drying, the glass yarn is transferred to a desiccator, left to stand for 20 minutes, and cooled to room temperature. After the cooling, the glass yarn is weighed in the unit of 0.1 mg or less. Next, the glass yarn is heated by a muffle furnace at 625° C. for 20 minutes. After the heating by the muffle furnace, the glass yarn is transferred to the desiccator, left to stand for 20 minutes, and cooled to room temperature. After the cooling, the glass yarn is weighed in the unit of 0.1 mg or less. The amount of the sizing agent attached to the glass yarn is expressed based on the ratio of the mass of the sizing agent (the difference between the mass of the glass yarn measured after drying and the mass of the glass yarn measured after the heating by the muffle furnace) to the mass of the glass yarn to which the sizing agent is attached.

Herein, the sizing agent of the glass cloth of the present invention does not substantially include the silane coupling agent. The sizing agent is almost completely removed by heating, water-cleaning or the like, after weaving of the glass cloth, and therefore, if including the silane coupling agent, can remain as a foreign substance on the glass surface.

The sizing agent preferably includes, for example, at least one selected from the group consisting of starch, polyvinyl alcohol, polyethylene oxide, polyester and polyamide.

The method of producing the glass cloth of the present embodiment includes, if the glass yarn surface is treated with the silane coupling agent, a method comprising a covering step of covering the glass filament surface with the silane coupling agent almost completely by use of a treatment liquid having a concentration of 0.1 to 3.0% by weight, a fixing step of fixing the silane coupling agent to the glass filament surface by heating and drying, and an adjustment step of cleaning at least a part of the silane coupling agent fixed on the glass filament surface with high-pressure spray water or the like to thereby adjust the amount of the silane coupling agent attached, so that the ignition loss is within a certain range.

As a solvent for dissolving or dispersing the silane coupling agent, any of water or an organic solvent can be used, and water is preferably used as a main solvent from the viewpoint of safety and global environment protection. A method of obtaining a treatment liquid including water as a main solvent is preferably any of a method comprising directly loading the silane coupling agent to water, and a method comprising dissolving the silane coupling agent in a water-soluble organic solvent to provide an organic solvent solution and then loading the organic solvent solution to water. In order to enhance water-dispersibility and stability of the silane coupling agent in the treatment liquid, a surfactant can also be used in combination.

The glass cloth is preferably subjected to the covering step, the fixing step and the adjustment step, after the weaving step. Furthermore, a spreading step of spreading the glass yarns of the glass cloth may be, if necessary, included after the weaving step. When the adjustment step is here performed after the weaving step, the adjustment step may also double as the spreading step. Herein, the composition of the glass cloth is not usually changed before and after spreading.

It is considered that the above production method can almost completely and uniformly form a silane coupling agent layer on the entire surface of each and every one of glass filaments configuring the glass yarn.

The method of applying the treatment liquid to the glass cloth can be, for example, a method (a) comprising storing the treatment liquid in a bath, and dipping and allowing passage of the glass cloth (hereinafter, referred to as “dip method”.), or a method (b) comprising directly applying the treatment liquid to the glass cloth by a roll coater, a die coater, a gravure coater or the like. In the case of application by the dipping method (a), the dipping time of the glass cloth in the treatment liquid is preferably selected within the range of 0.5 seconds or more but 1 minute or less.

The method of heating and drying the solvent after application of the treatment liquid to the glass cloth includes a known method by hot air, electromagnetic waves, or the like.

The heating/drying temperature is preferably 90° C. or more, more preferably 100° C. or more so that a reaction of the silane coupling agent and glass is sufficiently performed. In order to prevent degradation of the organic functional group in the silane coupling agent, the temperature is preferably 300° C. or less, more preferably 200° C. or less.

The spreading method of the spreading step is not particularly limited, and examples thereof include a method comprising processing the glass cloth by spreading with spray water (spreading with high-pressure water), Vibrowasher, ultrasonic water, mangle or the like. In processing by spreading, fluffing easily occurs in the case of a glass cloth having an amount of SiO₂ in the composition thereof of 98 to 100% by mass. On the contrary, the ignition loss of the glass cloth of the present embodiment can be 0.12% by mass or more to thereby suppress fluffing. In addition, in order to suppress reduction in tensile strength of the glass cloth due to processing by spreading, measures are preferably adopted such as reduction in friction with a contact member, and optimization of a binder and increase in the amount thereof attached, in glass yarn weaving. The tension to be applied to the glass cloth in processing by spreading can be decreased to thereby result in a tendency to impart a lower degree of air permeation.

Any step may also be included after the spreading step. Such any step is not particularly limited, and examples thereof include a slit-processing step.

After the glass cloth is surface-treated, a matrix resin is applied thereto to produce a prepreg. The storage period to the application of the matrix resin after the surface treatment of the glass cloth is preferably within 2 years. The storage temperature is preferably set to 10 to 40° C. When the storage temperature is 30° C. or less, the unsaturated double bond group of the silane coupling agent on the glass cloth surface can be suppressed in deactivation, to result in a tendency to maintain reactivity with the matrix resin. When the storage period is within 2 years, it tends to be able to suppress increase in bindability of a glass filament bundle due to a mutual reaction of the silane coupling agent by water attached on the glass surface. Thus, permeability of the matrix resin tends to be able to be enhanced.

Herein, examples of the method for producing the glass cloth of the present embodiment include a method comprising a step of adjusting conditions, for example, the standard deviation of migration attainment in weaving, the tension in a weaving machine and a processing machine, and the degree of parallelization between all rolls and all core tubes in the production process, to thereby adjust the warpage of a printed wiring board to be obtained, to 10 mm or less.

### [Prepreg]

A prepreg of the present embodiment includes the above glass cloth, and a matrix resin with which the glass cloth is impregnated. Thus, a prepreg can be provided which is thin and low in permittivity and which is enhanced in insulation reliability due to enhancement in insulation reliability and enhancement in moisture absorption resistance, in associated with the above respective reasons.

As the matrix resin, any of a thermosetting resin and a thermoplastic resin can be used. The thermosetting resin is not particularly limited, and examples thereof include a) an epoxy resin which is to be cured by a reaction of a compound having an epoxy group with a compound having at least one group reactive with an epoxy group, such as an amino group, a phenol group, an acid anhydride group, a hydrazide group, an isocyanate group, a cyanate group and a hydroxyl group in the absence of a catalyst or with addition of a catalyst having the ability as a reaction catalyst, such as an imidazole compound, a tertiary amine compound, a urea compound or a phosphorous compound; b) a radical polymerization-based curing resin which is to be cured by curing of a compound having at least one of an allyl group, a methacryl group and an acryl group with a thermal decomposition-based catalyst or a photo-decomposition-based catalyst as a reaction initiator; c) a maleimide triazine resin which is to be cured by a reaction of a compound having a cyanate group with a compound having a maleimide group; d) a thermosetting polyimide resin which is to be cured by a reaction of a maleimide compound with an amine compound; and e) a benzoxazine resin which is to be cured by crosslinking a compound having a benzoxazine ring by heating polymerization.

The thermoplastic resin is not particularly limited, and examples thereof include polyphenylene ether, modified polyphenylene ether, polyphenylene sulfide, polysulfone, polyethersulfone, polyarylate, aromatic polyamide, polyether ether ketone, thermoplastic polyimide, insoluble polyimide, polyamideimide and fluorine resins. The thermosetting resin and the thermoplastic resin may be used in combination.

### [Printed Wiring Board]

A printed wiring board of the present embodiment includes the prepreg. Thus, a printed wiring board low in permittivity and enhanced in insulation reliability can be provided.

### EXAMPLES

Next, the present invention is more specifically explained by means of Examples and Comparative Examples. The present invention is not intended to be limited by the following Examples at all.

### Example 1-1

A glass cloth woven from a glass yarn comprising glass filaments each having 98.5% by mass of SiO₂ (average filament diameter of glass filaments: 9 μm, the number of filaments: 100, weaving density of warp yarn: 54/inch, weaving density of weft yarn: 54/inch, thickness: 78 μm, mass: 69 g/m²) was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.13% by weight.

### Example 1-2

A glass cloth woven from a glass yarn comprising glass filaments each having 98.5% by mass of SiO₂ (average filament diameter of glass filaments: 9 μm, the number of filaments: 100, weaving density of warp yarn: 54/inch, weaving density of weft yarn: 54/inch, thickness: 78 μm, mass: 69 g/m²) was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.15% by weight.

### Example 1-3

A glass cloth woven from a glass yarn comprising glass filaments each having 98.5% by mass of SiO₂ (average filament diameter of glass filaments: 9 μm, the number of filaments: 100, weaving density of warp yarn: 54/inch, weaving density of weft yarn: 54/inch, thickness: 78 μm, mass: 69 g/m²) was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.21% by weight.

### Example 1-4

A glass cloth woven from a glass yarn comprising glass filaments each having 99.5% by mass of SiO₂ (average filament diameter of glass filaments: 9 μm, the number of filaments: 100, weaving density of warp yarn: 54/inch, weaving density of weft yarn: 54/inch, thickness: 78 μm, mass: 69 g/m²) was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.13% by weight.

### Example 1-5

A glass cloth woven from a glass yarn comprising glass filaments each having 98.5% by mass of SiO₂ (average filament diameter of glass filaments: 9 μm, the number of filaments: 100, weaving density of warp yarn: 54/inch, weaving density of weft yarn: 54/inch, thickness: 78 μm, mass: 69 g/m²) was dipped in a treatment liquid in which methacryloxypropyltrimethoxysilane (produced by Dow Corning Toray Co., Ltd.; Z 6030) was dispersed in water, and heated and dried. Next, spreading with high-pressure water was performed by spraying, and heating and drying was made to provide a product. The ignition loss of the glass cloth was 0.13% by weight.

### Example 1-6

A glass cloth woven from a glass yarn comprising glass filaments each having 98.5% by mass of SiO₂ (average filament diameter of glass filaments: 9 μm, the number of filament: 100, weaving density of warp yarn: 54/inch, weaving density of weft yarn: 54/inch, thickness: 78 μm, mass: 69 g/m²) was dipped in a treatment liquid in which N-β-(N-vinylbenzylaminoethyl)-γ-aminopropyltrimethoxysilane hydrochloride (produced by Dow Corning Toray Co., Ltd.; Z 6032) and methacryloxypropyltrimethoxysilane (produced by Dow Corning Toray Co., Ltd.; Z 6030) were dispersed in water, and heated and dried. Next, spreading with high-pressure water was performed by spraying, and heating and drying was made to provide a product. The ignition loss of the glass cloth was 0.13% by weight.

### Comparative Example 1-1

A glass cloth woven from a glass yarn comprising glass filaments each having 98.5% by mass of SiO₂ (average filament diameter of glass filaments: 9 μm, the number of filaments: 100, weaving density of warp yarn: 54/inch, weaving density of weft yarn: 54/inch, thickness: 78 μm, mass: 69 g/m²) was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.11% by weight.

### Comparative Example 1-2

A glass cloth woven from a glass yarn comprising glass filaments each having 98.5% by mass of SiO₂ (average filament diameter of glass filaments: 9 μm, the number of filaments: 100, weaving density of warp yarn: 54/inch, weaving density of weft yarn: 54/inch, thickness: 78 μm, mass: 69 g/m²) was dipped in a treatment liquid in which N-phenyl-aminopropyltrimethoxysilane (produced by Shin-Etsu Silicone; KBM 573) was dispersed in water, and heated and dried. Next, spreading with high-pressure water was performed by spraying, and heating and drying was made to provide a product. The ignition loss of the glass cloth was 0.13% by weight.

### Comparative Example 1-3

A glass cloth woven from a glass yarn comprising glass filaments each having 95% by mass of SiO₂ (average filament diameter of glass filaments: 9 μm, the number of filaments: 100, weaving density of warp yarn: 54/inch, weaving density of weft yarn: 54/inch, thickness: 78 μm, mass: 69 g/m²) was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.13% by weight.

### Example 2-1

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.22% by mass.

### Example 2-2

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.32% by mass.

### Example 2-3

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.85% by mass.

### Example 2-4

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 59% by mass and an amount of B₂O₃ in the composition thereof of 16% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.22% by mass.

### Example 2-5

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which methacryloxypropyltrimethoxysilane (produced by Dow Corning Toray Co., Ltd.; Z 6030) was dispersed in water, and heated and dried. Next, spreading with high-pressure water was performed by spraying, and heating and drying was made to provide a product. The ignition loss of the glass cloth was 0.22% by mass.

### Example 2-6

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) and methacryloxypropyltrimethoxysilane (produced by Dow Corning Toray Co., Ltd.; Z 6030) were dispersed in water, and heated and dried. Next, spreading with high-pressure water was performed by spraying, and heating and drying was made to provide a product. The ignition loss of the glass cloth was 0.22% by mass.

### Example 2-7

A weft yarn comprising glass filaments each having an amount of SiO₂ in the composition thereof of 98.5% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.22% by mass.

### Comparative Example 2-1

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-phenyl-aminopropyltrimethoxysilane (produced by Shin-Etsu Silicone; KBM 573) was dispersed in water, and heated and dried. Next, spreading with high-pressure water was performed by spraying, and heating and drying was made to provide a product. The ignition loss of the glass cloth was 0.22% by mass.

### Comparative Example 2-2

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 1.1% by mass.

### Example 3-1

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.32% by mass. The bias filling of the weft yarn of the glass cloth was 5 mm.

### Example 3-2

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.32% by mass. The bias filling of the weft yarn of the glass cloth was 10 mm.

### Example 3-3

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.32% by mass. The bias filling of the weft yarn of the glass cloth was 18 mm.

### Example 3-4

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 59% by mass and an amount of B₂O₃ in the composition thereof of 16% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.32% by mass. The bias filling of the weft yarn of the glass cloth was 10 mm.

### Example 3-5

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 99.9% by mass (average filament diameter of glass filaments: 9 μm, the number of filaments: 100, weaving density: 54/inch) were used to weave a glass cloth (thickness: 78 μm, cloth weight: 69 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.24% by mass. The bias filling of the weft yarn of the glass cloth was 10 mm.

### Example 3-6

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.32% by mass. The bias filling of the weft yarn of the glass cloth was 22 mm.

### Example 3-7

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch) were used to weave a glass cloth (thickness: 78 μm, cloth weight: 70 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.32% by mass. The bias filling of the weft yarn of the glass cloth was 30 mm.

### Example 3-8

A weft yarn comprising glass filaments each having an amount of SiO₂ in the composition thereof of 99.9% by mass (average filament diameter of glass filaments: 9 μm, the number of filaments: 100, weaving density: 54/inch) and a warp yarn comprising glass filaments each having an amount of SiO₂ in the composition thereof of 99.9% by mass (average filament diameter of glass filaments: 9 μm, the number of filaments: 100, weaving density: 54/inch) were used to weave a glass cloth (thickness: 78 μm, cloth weight: 69 g/m²). The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.24% by mass. The bias filling of the weft yarn of the glass cloth was 21 mm.

### Example 4-1

A sizing step of applying an aqueous sizing agent solution including polyvinyl alcohol in a concentration of 5% by mass according to a dipping method to attach a sizing agent to a glass yarn was performed, to produce a weft yarn, in which the amount of the sizing agent attached in the sizing step was 2.2% by mass, comprising glass filaments each having an amount of SiO₂ in the composition thereof of 99.9% by mass (average filament diameter of glass filaments: 9 μm, the number of filaments: 100, weaving density: 54/inch).

The same manner was made to produce a warp yarn, in which the amount of the sizing agent attached in the sizing step was 2.1% by mass, comprising glass filaments each having an amount of SiO₂ in the composition thereof of 53% by mass and an amount of B₂O₃ in a composition thereof of 23% by mass (average filament diameter of glass filaments: 6 μm, the number of filaments: 200, weaving density: 61/inch).

The warp yarn and the weft yarn obtained as described above were used to weave a glass cloth (thickness: 78 μm, cloth weight: 70 g/m²). The glass cloth woven was subjected to a desizing step of removing the sizing agent by heating at 400° C. The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.32% by mass.

### Example 4-2

A sizing step of applying an aqueous sizing agent solution including polyvinyl alcohol in a concentration of 5% by mass according to a dipping method to attach a sizing agent to a glass yarn was performed, to produce a weft yarn, in which the amount of the sizing agent attached in the sizing step was 3.0% by mass, comprising glass filaments each having an amount of SiO₂ in the composition thereof of 99.9% by mass (average filament diameter of glass filaments: 9 μm, the number of filaments: 100, weaving density: 54/inch).

The same manner was made to produce a warp yarn, in which the amount of the sizing agent attached in the sizing step was 3.0% by mass, comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch).

The warp yarn and the weft yarn obtained as described above were used to weave a glass cloth (thickness: 78 μm, cloth weight: 70 g/m²). The glass cloth woven was subjected to a desizing step of removing the sizing agent by heating at 400° C. The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.32% by mass.

### Example 4-3

A sizing step of applying an aqueous sizing agent solution including polyvinyl alcohol in a concentration of 5% by mass according to a dipping method to attach a sizing agent to a glass yarn was performed, to produce a weft yarn, in which the amount of the sizing agent attached in the sizing step was 3.5% by mass, comprising glass filaments each having an amount of SiO₂ in the composition thereof of 99.9% by mass (average filament diameter of glass filaments: 9 μm, the number of filaments: 100, weaving density: 54/inch).

The same manner was made to produce a warp yarn, in which the amount of the sizing agent attached in the sizing step was 3.5% by mass, comprising glass filaments each having an amount of SiO₂ in the composition thereof of 53% by mass and an amount of B₂O₃ in the composition thereof of 23% by mass (average filament diameter of glass filaments: 6 μm, the number of filaments: 200, weaving density: 61/inch).

The warp yarn and the weft yarn obtained as described above were used to weave a glass cloth (thickness: 78 μm, cloth weight: 70 g/m²). The glass cloth woven was subjected to a desizing step of removing the sizing agent by heating at 400° C. The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.32% by mass.

### Example 4-4

A sizing step of applying an aqueous sizing agent solution including polyvinyl alcohol in a concentration of 5% by mass according to a dipping method to attach a sizing agent to a glass yarn was performed, to produce a weft yarn, in which the amount of the sizing agent attached in the sizing step was 2.6% by mass, comprising glass filaments each having an amount of SiO₂ in the composition thereof of 99.9% by mass (average filament diameter of glass filaments: 9 μm, the number of filaments: 100, weaving density: 54/inch).

The same manner was made to produce a warp yarn, in which the amount of the sizing agent attached in the sizing step was 2.6% by mass, comprising glass filaments each having an amount of SiO₂ in the composition thereof of 99.9% by mass (average filament diameter of glass filaments: 9 μm, the number of filaments: 100, weaving density: 54/inch).

The warp yarn and the weft yarn obtained as described above were used to weave a glass cloth (thickness: 78 μm, cloth weight: 69 g/m²). The glass cloth woven was subjected to a desizing step of removing the sizing agent by heating at 400° C. The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.24% by mass.

### Example 4-5

A sizing step of applying an aqueous sizing agent solution including polyvinyl alcohol in a concentration of 5% by mass according to a dipping method to attach a sizing agent to a glass yarn was performed, to produce a weft yarn, in which the amount of the sizing agent attached in the sizing step was 3.7% by mass, comprising glass filaments each having an amount of SiO₂ in the composition thereof of 99.9% by mass (average filament diameter of glass filaments: 9 μm, the number of filaments: 100, weaving density: 54/inch).

The same manner was made to produce a warp yarn, in which the amount of the sizing agent attached in the sizing step was 3.6% by mass, comprising glass filaments each having an amount of SiO₂ in the composition thereof of 99.9% by mass (average filament diameter of glass filaments: 9 μm, the number of filaments: 100, weaving density: 54/inch).

The warp yarn and the weft yarn obtained as described above were used to weave a glass cloth (thickness: 78 μm, cloth weight: 69 g/m²). The glass cloth woven was subjected to a desizing step of removing the sizing agent by heating at 400° C. The resulting glass cloth was dipped in a treatment liquid in which N-β-(N-vinylbenzylaminoethyl)-γ-aminopropyltrimethoxysilane hydrochloride (produced by Dow Corning Toray Co., Ltd.; Z 6032) was dispersed in water, and heated and dried. Next, spreading with high-pressure water was performed by spraying, and heating and drying was made to provide a product. The ignition loss of the glass cloth was 0.24% by mass.

### <Evaluation Method of Ignition Loss of Glass Cloth>

The ignition loss was measured according to the method described in JIS R 3420. Specifically, the glass cloth was placed in a drier at 105° C.±5° C., and dried for at least 30 minutes. After the drying, the glass cloth was transferred to a desiccator, and cooled to room temperature. After the cooling, the weight of the glass cloth was measured in the unit of 0.1 mg or less. Next, the glass cloth was heated by a muffle furnace at about 625° C. for 20 minutes. After the heating by the muffle furnace, the glass cloth was transferred to a desiccator, and cooled to room temperature. After the cooling, the weight of the glass cloth was measured in the unit of 0.1 mg or less. The change in the weight of the muffle furnace before and after the heating was measured, and the ignition loss was calculated as the amount of a treatment agent attached.

### <Evaluation Method of Amount of Sizing Agent Attached>

The amount of the sizing agent attached was measured according to the method described in JIS R 3420. Specifically, the glass yarn to which the sizing agent was attached was placed in a drier at 110° C., and dried for 60 minutes. After the drying, the glass yarn was transferred to a desiccator, left to stand for 20 minutes, and cooled to room temperature. After the cooling, the glass yarn was measured in the unit of 0.1 mg or less. Next, the glass yarn was heated by a muffle furnace at 625° C. for 20 minutes. After the heating by the muffle furnace, the glass yarn was transferred to a desiccator, left to stand for 20 minutes, and cooled to room temperature. After the cooling, the glass yarn was measured in the unit of 0.1 mg or less. The ignition loss determined by the above measurement method was used to determine the amount of the sizing agent attached to the glass yarn (the ratio of the mass of the sizing agent (the difference between the mass of the glass yarn measured after drying and the mass of the glass yarn measured after the heating by the muffle furnace) to the mass of the glass yarn to which the sizing agent was attached).

### <Measurement Method of Bias Filling>

The bias filling between the weft yarn and the warp yarn was measured according to the method described in JIS L 1096.

### <Evaluation Method of Thickness of Glass Cloth>

A spindle was gently rotated and lightly brought into contact with the measurement surface in parallel according to 7.10 in JIS R 3420 by use of a micrometer. The scale after a ratchet sounded three times was read.

### <Fluff Evaluation (Bending Resistance Evaluation) 1 of Glass Cloth>

With respect to each of Example 1-1 to Comparative Example 1-3, Example 2-1 to Comparative Example 2-2 and Example 3-1 to Example 3-8, the resulting glass cloth was impregnated with a polyphenylene ether resin varnish (mixture of 30 parts by mass of a modified polyphenylene ether resin, 10 parts by mass of triallyl isocyanurate, 60 parts by mass of toluene and 0.1 parts by mass of a catalyst) and dried at 120° C. for 2 minutes, and thereafter a prepreg was obtained. The resin content in the prepreg was adjusted to 50% by mass. Next, a small piece sample of 100 mm×100 mm at any location was cut out, and the number of protrusion parts was visually determined.

### <Fluff Evaluation (Bending Resistance Evaluation) 2 of Glass Cloth>

With respect to each of Example 4-1 to Example 4-5, the resulting glass cloth was loaded with a tension of 100 N/1000 mm on a Roll-to-Roll inspection bench under irradiation by a halogen lamp, and the number of protrusion parts of 1 mm or more per square meter was visually determined.

### <Substrate Preparation Method 1>

With respect to each of Example 1-1 to Comparative Example 1-3, Example 2-1 to Comparative Example 2-2 and Example 4-1 to Example 4-5, the resulting glass cloth was impregnated with a polyphenylene ether resin varnish (mixture of 30 parts by mass of a modified polyphenylene ether resin, 10 parts by mass of triallyl isocyanurate, 60 parts by mass of toluene and 0.1 parts by mass of a catalyst) and dried at 120° C. for 2 minutes, and thereafter a prepreg was obtained. The prepreg was stacked, copper foil having a thickness of 12 μm was further stacked thereon and thereunder, and the resultant was heated and compressed at 200° C. and 40 kg/cm² for 60 minutes to provide a substrate.

### <Substrate Preparation Method 2>

With respect to each of Example 3-1 to Example 3-8, the resulting glass cloth was impregnated with an epoxy resin varnish (mixture of 40 parts by mass of low-brominated bisphenol A type epoxy resin (produced by DIC Corp., 1121N-80M), 10 parts by mass of an o-cresol-based novolac epoxy resin (produced by DIC Corp., N680-75M), 50 parts by mass of 2-methoxyethanol, 1 part by mass of dicyandiamide and 0.1 parts by mass of 2-ethyl-4-methylimidazole) and dried at 120° C. for 2 minutes, and thereafter a prepreg was obtained. The prepreg was stacked, copper foil having a thickness of 12 μm was further stacked thereon and thereunder, and the resultant was heated and compressed at 200° C. and 40 kg/cm² for 60 minutes to provide a substrate.

### <Evaluation Method of Warpage of Substrate>

With respect to each of Example 3-1 to Example 3-8, a substrate was prepared as described above so that the resin content per 100% by mass of the prepreg was 60% by mass, and the copper foil was removed to provide a sample for warpage evaluation. The resulting sample was cut to a size of 50 mm×200 mm, heated at 200° C. for 30 minutes, and placed on a flat table and cooled to room temperature, and the warpage height of each of four piece samples was measured. The maximum value among the four pieces was determined as the substrate warpage.

### <Evaluation Method of Dimensional Change of Substrate>

With respect to each of Example 3-1 to Example 3-8, a substrate was prepared as described above so that the resin content per 100% by mass of the prepreg was 60% by mass, and cut to a size of 350 mm×350 mm to provide a sample for dimension evaluation. The resulting sample was processed by a 0.5-mmΦ drill so that nine through-holes were made at an interval of 100 mm, and position (A) was determined with a three dimensional measuring machine (manufactured by Nikon Corporation; VM-500N). Furthermore, the copper foil of the sample was removed, heated at 200° C. for 30 minutes and cooled to room temperature, and position (B) of each of the nine through-holes was determined. The maximum value of the change rate between position (A) and position (B) was determined as the dimensional change of the substrate.

### <Evaluation Method of Permittivity of Each of Substrate and Glass Cloth>

A substrate was prepared as described above so that the resin content per 100% by mass of the prepreg was 60% by mass, and the copper foil was removed to provide a sample for permittivity evaluation. The permittivity of the resulting sample at a frequency of 1 GHz was measured using an impedance analyzer (manufactured by Agilent Technologies). The permittivity of the resulting substrate was used to calculate the permittivity of the glass cloth based on the volume fraction of the glass cloth and a resin permittivity of 2.5.

### <Evaluation Method of Insulation Reliability of Substrate>

A substrate was prepared as described above so as to have a thickness of 0.4 mm, and a wiring pattern where a through-hole was disposed at an interval of 0.15 mm was prepared on the copper foil on each of both surfaces of the substrate, to provide a sample for insulation reliability evaluation. A voltage of 10 V was applied to the resulting sample under an atmosphere of a temperature of 120° C. and a humidity of 85% RH, to measure the change in resistance value. Here, a case where the resistance obtained was less than 1 MΩ within 500 hours after the start of the test was counted as insulation failure. Ten samples were subjected to the same measurement, and the proportion of sample(s) not rated as insulation failure, among the ten samples, was calculated.

### <Evaluation Method of Interlayer Insulation Reliability of Substrate>

A substrate was prepared as described above so as to have a thickness of 0.1 mm, and the copper foil on each of both surfaces of the substrate was partially etched by an aqueous iron chloride solution to allow a copper foil portion of 10 mmΦ to remain on each of both surfaces of the substrate, thereby providing a sample for interlayer insulation reliability evaluation. A voltage of 10 V was applied to the resulting sample under an atmosphere of a temperature of 120° C. and a humidity of 85% RH, to measure the change in resistance value. Here, a case where the resistance obtained was less than 1 MO within 500 hours after the start of the test was counted as insulation failure. Ten samples were subjected to the same measurement, and the proportion of sample(s) not rated as insulation failure, among the ten samples, was calculated.

The evaluation results of the glass cloth shown in each of Examples and Comparative Examples were summarized in Tables.

TABLE 1

| | Amount of | | | Prepreg | Substrate | |
|---|---|---|---|---|---|---|
| | SiO₂ in | Glass cloth | | Number of | | Insulation |
| | composition | Ignition loss | Permittivity | fluffs | Permittivity | reliability |
| Example 1-1 | 98.5 | 0.13 | 3.7 | 2 | 3.3 | 80% |
| Example 1-2 | 98.5 | 0.15 | 3.7 | 1 | 3.3 | 90% |
| Example 1-3 | 98.5 | 0.21 | 3.7 | 0 | 3.3 | 100% |
| Example 1-4 | 99.5 | 0.13 | 3.7 | 4 | 3.3 | 80% |
| Example 1-5 | 98.5 | 0.13 | 3.7 | 2 | 3.3 | 80% |
| Example 1-6 | 98.5 | 0.13 | 3.7 | 2 | 3.3 | 100% |
| Comparative | 98.5 | 0.11 | 3.7 | 10 | 3.3 | 10% |
| Example 1-1 | | | | | | |
| Comparative | 98.5 | 0.13 | 3.7 | 4 | 3.3 | 0% |
| Example 1-2 | | | | | | |
| Comparative | 95.0 | 0.13 | 4.0 | 2 | 3.6 | 0% |
| Example 1-3 | | | | | | |

It was found that the glass cloth of each Example in Table 1 was low in permittivity and very excellent in insulation reliability.

TABLE 2

| | | | | | | | Glass cloth |
|---|---|---|---|---|---|---|---|
| | Warp yarn | | | Weft yarns | | | Weaving |
| | SiO₂/B₂O₃ | Filament | Number of | SiO₂ | Filament | Number of | density (weft |
| | composition | diameter | filaments | composition | diameter | filaments | yarn * warp |
| | (% by mass) | (μm) | (filaments) | (% by mass) | (μm) | (filaments) | yarn) (/inch) |
| Example 2-1 | 53/23 | 6 | 200 | 99.9 | 9 | 100 | 54 * 61 |
| Example 2-2 | 53/23 | 6 | 200 | 99.9 | 9 | 100 | 54 * 61 |
| Example 2-3 | 53/23 | 6 | 200 | 99.9 | 9 | 100 | 54 * 61 |
| Example 2-4 | 59/16 | 6 | 200 | 99.9 | 9 | 100 | 54 * 61 |
| Example 2-5 | 53/23 | 6 | 200 | 99.9 | 9 | 100 | 54 * 61 |
| Example 2-6 | 53/23 | 6 | 200 | 99.9 | 9 | 100 | 54 * 61 |
| Example 2-7 | 53/23 | 6 | 200 | 98.5 | 9 | 100 | 54 * 61 |
| Comparative | 53/23 | 6 | 200 | 99.9 | 9 | 100 | 54 * 61 |
| Example 2-1 | | | | | | | |
| Comparative | 53/23 | 6 | 200 | 99.9 | 9 | 100 | 54 * 61 |
| Example 2-2 | | | | | | | |

| | Glass cloth | | | | | | |
|---|---|---|---|---|---|---|---|
| | | Cloth | Ignition | | Prepreg | Substrate | |
| | Thickness | weight | loss (% by | | Number | | Insulation |
| | (μm) | (g/m²) | mass) | Permittivity | of fluffs | Permittivity | reliability |
| Example 2-1 | 78 | 70 | 0.22 | 4.1 | 3 | 3.4 | 80% |
| Example 2-2 | 78 | 70 | 0.32 | 4.1 | 2 | 3.4 | 100% |
| Example 2-3 | 78 | 70 | 0.85 | 4.1 | 0 | 3.4 | 80% |
| Example 2-4 | 78 | 70 | 0.22 | 4.1 | 5 | 3.4 | 70% |
| Example 2-5 | 78 | 70 | 0.22 | 4.1 | 3 | 3.4 | 80% |
| Example 2-6 | 78 | 70 | 0.22 | 4.1 | 2 | 3.4 | 100% |
| Example 2-7 | 78 | 70 | 0.22 | 4.1 | 1 | 3.4 | 80% |
| Comparative | 78 | 70 | 0.22 | 4.1 | 4 | 3.4 | 10% |
| Example 2-1 | | | | | | | |
| Comparative | 78 | 70 | 1.1 | 4.1 | 3 | 3.4 | 0% |
| Example 2-2 | | | | | | | |

It was found that the substrate obtained by using the glass cloth of each Example in Table 2 was low in permittivity and very excellent in insulation reliability.

TABLE 3

| | Warp yarn | | | | Weft yarn | | | | Glass cloth |
|---|---|---|---|---|---|---|---|---|---|
| | SiO₂/B₂O₃ | Filament | Number of | Tensile | SiO₂/B₂O₃ | Filament | Number of | Tensile | Bias filling |
| | composition | diameter | filaments | modulus | composition | diameter | filaments | modulus | of Weft |
| | (% by mass) | (μm) | (filaments) | (Gpa) | (% by mass) | (μm) | (filaments) | (Gpa) | yarn (mm) |
| Example 3-1 | 53/23 | 6 | 200 | 62 | 99.9/0 | 9 | 100 | 78 | 5 |
| Example 3-2 | 53/23 | 6 | 200 | 62 | 99.9/0 | 9 | 100 | 78 | 10 |
| Example 3-3 | 53/23 | 6 | 200 | 62 | 99.9/0 | 9 | 100 | 78 | 18 |
| Example 3-4 | 59/16 | 6 | 200 | 65 | 99.9/0 | 9 | 100 | 78 | 10 |
| Example 3-5 | 99.9/0 | 9 | 100 | 78 | 99.9/0 | 9 | 100 | 78 | 10 |
| Example 3-6 | 53/23 | 6 | 200 | 62 | 99.9/0 | 9 | 100 | 78 | 22 |
| Example 3-7 | 53/23 | 6 | 200 | 62 | 99.9/0 | 9 | 100 | 78 | 30 |
| Example 3-8 | 99.9/0 | 9 | 100 | 78 | 99.9/0 | 9 | 100 | 78 | 21 |

| | Glass cloth | | | | | | | | |
|---|---|---|---|---|---|---|---|---|---|
| | Weaving | | | | | | | | |
| | density (weft | | Cloth | Ignition | | Prepreg | Substrate (printed wiring board) | | |
| | yarn * warp | Thickness | weight | loss (% | | Number of | | Warpage | Dimensional |
| | yarn) (/inch) | (μm) | (g/m²) | by mass) | Permittivity | fluffs | Permittivity | (mm) | change |
| Example 3-1 | 54 * 61 | 78 | 70 | 0.32 | 4.1 | 2 | 3.4 | 0 | 0.1 |
| Example 3-2 | 54 * 61 | 78 | 70 | 0.32 | 4.1 | 2 | 3.4 | 1 | 0.1 |
| Example 3-3 | 54 * 61 | 78 | 70 | 0.32 | 4.1 | 3 | 3.4 | 2 | 0.2 |
| Example 3-4 | 54 * 61 | 78 | 70 | 0.32 | 4.1 | 5 | 3.4 | 1 | 0.1 |
| Example 3-5 | 54 * 54 | 78 | 69 | 0.24 | 3.6 | 7 | 3.1 | 1 | 0.1 |
| Example 3-6 | 54 * 61 | 78 | 70 | 0.32 | 4.1 | 10 | 3.4 | 12 | 0.7 |
| Example 3-7 | 54 * 61 | 78 | 70 | 0.32 | 4.1 | 4 | 3.4 | 20 | 1 |
| Example 3-8 | 54 * 54 | 78 | 69 | 0.24 | 3.6 | 13 | 3.1 | 10 | 0.5 |

It was found that the substrate obtained by using the glass cloth of each Example in Table 3 was low in permittivity and very excellent in substrate warpage and dimensional change.

TABLE 4

| | | | | Warp yarn | | | | |
|---|---|---|---|---|---|---|---|---|
| | | Warp yarn | Warp yarn | Amount of | Warp yarn | | Weft yarn | Weft yarn |
| | Warp yarn | Filament | Number of | sizing agent | Number in Z | Weft yarn | Filament | Number of |
| | SiO₂/B₂O₃ | diameter | filaments | attached | direction | SiO₂/B₂O₃ | diameter | filaments |
| | composition | (μm) | (filaments) | (% by mass) | (/m²) | composition | (μm) | (filaments) |
| Example 4-1 | 53/23 | 6 | 200 | 2.1 | 7 | 99.9/0 | 9 | 100 |
| Example 4-2 | 53/23 | 6 | 200 | 3.0 | 7 | 99.9/0 | 9 | 100 |
| Example 4-3 | 53/23 | 6 | 200 | 3.5 | 7 | 99.9/0 | 9 | 100 |
| Example 4-4 | 99.9/0 | 9 | 100 | 2.6 | 5 | 99.9/0 | 9 | 100 |
| Example 4-5 | 99.9/0 | 9 | 100 | 3.6 | 5 | 99.9/0 | 9 | 100 |

| | Weft yarn | | | | | Laminate | |
|---|---|---|---|---|---|---|---|
| | Amount of | Weft yarn | | | | Interlayer | Laminate |
| | sizing agent | Number in | | Cloth | | insulation | Insulation |
| | attached | Z direction | Cloth | Number | Laminate | property | property |
| | (% by mass) | (/m²) | Permittivity | of fluffs | Permittivity | (%) | (%) |
| Example 4-1 | 2.2 | 4 | 4.1 | 8 | 3.4 | 100 | 100 |
| Example 4-2 | 3.0 | 4 | 4.1 | 5 | 3.4 | 100 | 100 |
| Example 4-3 | 3.5 | 4 | 4.1 | 3 | 3.4 | 100 | 100 |
| Example 4-4 | 2.6 | 4 | 3.6 | 7 | 3.1 | 100 | 100 |
| Example 4-5 | 3.7 | 4 | 3.6 | 6 | 3.1 | 100 | 100 |

It was found that the substrate obtained by using the glass cloth of each Example in Table 4 was low in permittivity and very excellent in insulation reliability.

The present application is based on Japanese Patent Application (Japanese Patent Application No. 2017-023527) filed on Feb. 10, 2017, Japanese Patent Application (Japanese Patent Application No. 2017-023533) filed on Feb. 10, 2017, Japanese Patent Application (Japanese Patent Application No. 2017-023535) filed on Feb. 10, 2017, and Japanese Patent Application (Japanese Patent Application No. 2017-023560) filed on Feb. 10, 2017, the contents of which are herein incorporated as reference.

### INDUSTRIAL APPLICABILITY

The glass cloth of the present invention has industrial applicability to a base material for use in a printed wiring board used in the electronic and electrical fields.

1. A glass cloth comprising a warp yarn and a weft yarn woven together, the warp yarn and the weft yarn each being a glass yarn comprising multiple glass filaments, wherein
at least one of the warp yarn and the weft yarn comprises filaments each having an amount of SiO₂ in a composition thereof of 98 to 100% by mass,
an average filament diameter of the glass filaments is 3 to 10 μm,
number of the glass filaments is 20 to 300,
each of weaving densities of the warp yarn and the weft yarn configuring the glass cloth is independently 20 to 140/inch,
a thickness of the glass cloth is 5 to 100 μm,
an ignition loss of the glass cloth is 0.12% by mass or more but 1.0% by mass or less,
a permittivity of the glass cloth is 4.4 or less, and
a surface of the glass yarn is treated with a silane coupling agent having an unsaturated double bond group.

2. The glass cloth according to claim 1, wherein
one of the warp yarn and the weft yarn is a glass yarn comprising glass filaments each having an amount of SiO₂ in a composition thereof of 98 to 100% by mass, and
the other of the warp yarn and the weft yarn is a glass yarn comprising glass filaments each having an amount of SiO₂ in a composition thereof of 45 to 60% by mass and amount of B₂O₃ in a composition thereof of 15 to 30% by mass.

3. The glass cloth according to claim 1, wherein a warpage of a printed wiring board formed by the glass cloth is 10 mm or less.

4. The glass cloth according to claim 2, wherein
a tensile modulus of the glass yarn having an amount of SiO₂ in a composition thereof of 98 to 100% by mass is 70 GPa or more, and
a ratio of the tensile modulus of the glass yarn having an amount of SiO₂ in a composition thereof of 98 to 100% by mass to a tensile modulus of the glass yarn having an amount of SiO₂ in a composition thereof of 45 to 60% by mass and amount of B₂O₃ in a composition thereof of 15 to 30% by mass is 1.3 or less.

5. The glass cloth according to claim 1, wherein a bias filling between the weft yarn and the warp yarn of the glass cloth is 0 to 20 mm per meter as measured with the glass yarns of one of the weft yarn and the warp yarn vertically located.

6. The glass cloth according to claim 1, wherein number of fluffs having a length of 1 mm or more, as observed in application of a tension of 100 N/1000 mm by Roll-to-Roll, is 10/m² or less.

7. The glass cloth according to claim 1, wherein the number of the glass filaments of each of the warp yarn and the weft yarn, aligned in a Z direction, is independently 8 or less.

8. The glass cloth according to claim 1, wherein the surface of the glass yarn is treated with two or more of the silane coupling agents different in molecular weight.

9. A prepreg comprising the glass cloth according to claim 1, and a matrix resin with which the glass cloth is impregnated.

10. A printed wiring board comprising the prepreg according to claim 9.
